(19) United States
(12) Patent Application Publication
(10) Pub. No.: US 2026/0005112 A1
(43) Pub. Date: Jan. 1, 2026

(54) SEMICONDUCTOR PACKAGE

(71) Applicant: Samsung Electronics Co., Ltd., Suwon-si (KR)

(72) Inventors: Yeonghyeon GIM, Suwon-si (KR); Junho Lee, Suwon-si (KR)

(21) Appl. No.: 18/983,816

(22) Filed: Dec. 17, 2024

(30) Foreign Application Priority Data
Jul. 1, 2024 (KR) 10-2024-0086238

(51) Int. Cl. H01L 23/498; H01L 23/00; H01L 23/538; H01L 25/065; H01L 25/18; H10B 80/00; H10D 80/30

(52) U.S. Cl. CPC H01L 23/49816; H01L 24/13; H01L 24/16; H01L 23/5385; H01L 25/0652; H01L 25/0657; H01L 25/18; H01L 2224/13016; H01L 2224/13082; H01L 2224/13147; H01L 2224/13155; H01L 2224/13611; H01L 2224/13613; H01L 2224/13639; H01L 2224/13647; H01L 2224/16227; H01L 2225/06517; H01L 2225/0652; H01L 2924/3511; H10B 80/00; H10D 80/30

(57) ABSTRACT

A semiconductor package may include a package substrate including a substrate pad, a solder ball in contact with a bottom surface of the substrate pad, and a core enclosed by the solder ball. An area of a bottom surface of the core may be larger than an area of a top surface of the core.

### CROSS-REFERENCE TO RELATED APPLICATIONS

This U.S. non-provisional patent application claims priority under 35 U.S.C. § 119 to Korean Patent Application No. 10-2024-0086238, filed on Jul. 1, 2024, in the Korean Intellectual Property Office, the entire contents of which are hereby incorporated by reference.

### BACKGROUND OF THE INVENTION

The present disclosure relates to a semiconductor package, and in particular, to a semiconductor package including a solder ball and a core in the solder ball.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB using bonding wires or bumps. With development of the semiconductor industry, many studies are being conducted to improve reliability of the semiconductor package.

### SUMMARY

An embodiment of the inventive concept provides a semiconductor package with improved electrical and reliability characteristics.

According to an embodiment of the inventive concept, a semiconductor package may include a package substrate including a substrate pad, a solder ball in contact with a bottom surface of the substrate pad, and a core enclosed by the solder ball. An area of a bottom surface of the core may be larger than an area of a top surface of the core.

According to an embodiment of the inventive concept, a semiconductor package may include a package substrate including a substrate pad, a solder ball in contact with a bottom surface of the substrate pad, and a core enclosed by the solder ball. A volume of a lower portion of the core may be larger than a volume of an upper portion of the core.

According to an embodiment of the inventive concept, a semiconductor package may include a package substrate including a connection pattern, a semiconductor device on the substrate, a mold layer disposed on the substrate to cover the semiconductor device, a stiffener disposed on the substrate to enclose the mold layer, a solder ball in contact with a bottom surface of the connection pattern, and a core enclosed by the solder ball. A top surface and a bottom surface of the core may have a circular shape, and a diameter of the bottom surface of the core may be larger than a diameter of the top surface of the core.

### BRIEF DESCRIPTION OF THE DRAWINGS

FIG. 1A is a sectional view illustrating a semiconductor package according to some embodiments.

FIG. 1B is an enlarged view illustrating a portion ‘A’ of FIG. 1A.

FIG. 1C is a plan view illustrating a core of the semiconductor package of FIGS. 1A and 1B.

FIG. 1D is a sectional view illustrating a semiconductor package system, on which the semiconductor package of FIG. 1A is mounted.

FIGS. 2A, 2B, 2C, 2D, and 2E are sectional views illustrating a method of fabricating a semiconductor package according to FIGS. 1A, 1B, and 1C.

FIG. 3 is a sectional views illustrating a core of a semiconductor package according to further embodiments.

FIG. 4 is a sectional view illustrating a core of a semiconductor package according to further embodiments.

FIG. 5 is a sectional view illustrating a core of a semiconductor package according to further embodiments.

FIG. 6 is a sectional view illustrating a semiconductor package according to further embodiments.

FIG. 7 is a sectional view illustrating a semiconductor package according to further embodiments.

FIG. 8 is a sectional view illustrating a semiconductor package according to further embodiments.

### DETAILED DESCRIPTION

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

For the purpose of explanation, certain dimensions of components are described herein as a component's “width” and the component's “length”. Unless otherwise specified, the use of these terms is not intended to mean that the width of the component is necessarily less than its length.

Example embodiments will now be described more fully with reference to the accompanying drawings, in which example embodiments are shown.

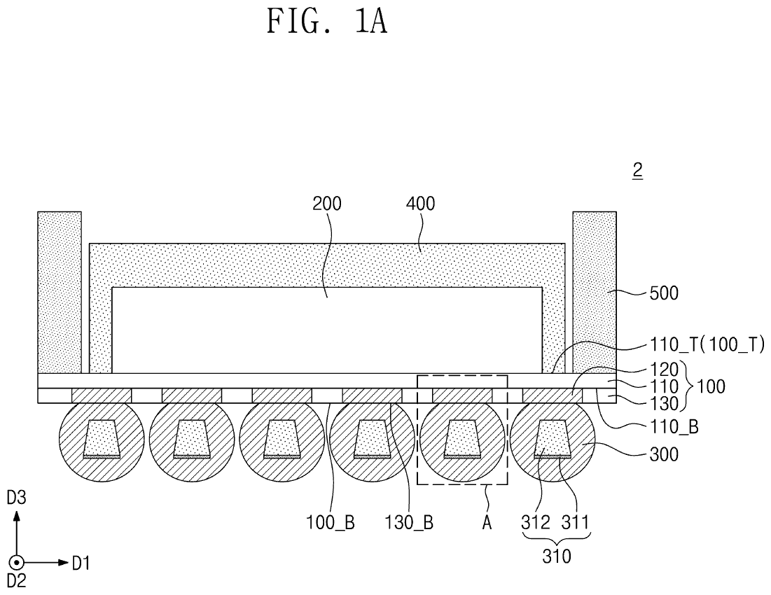

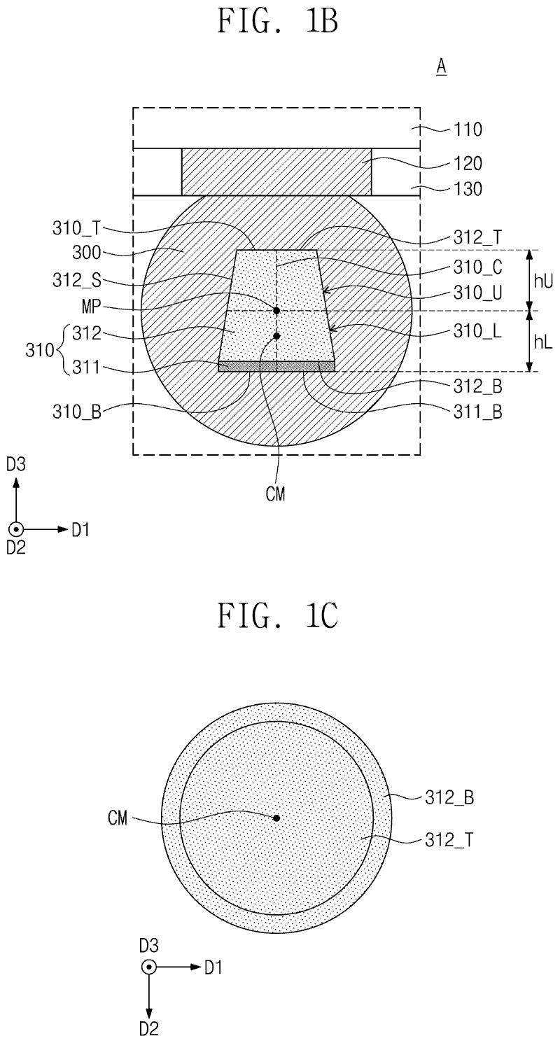

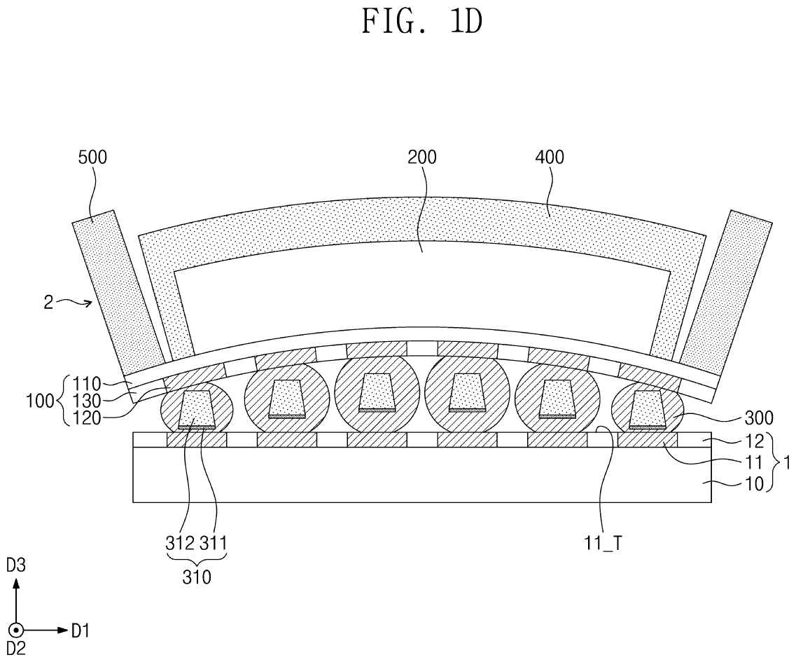

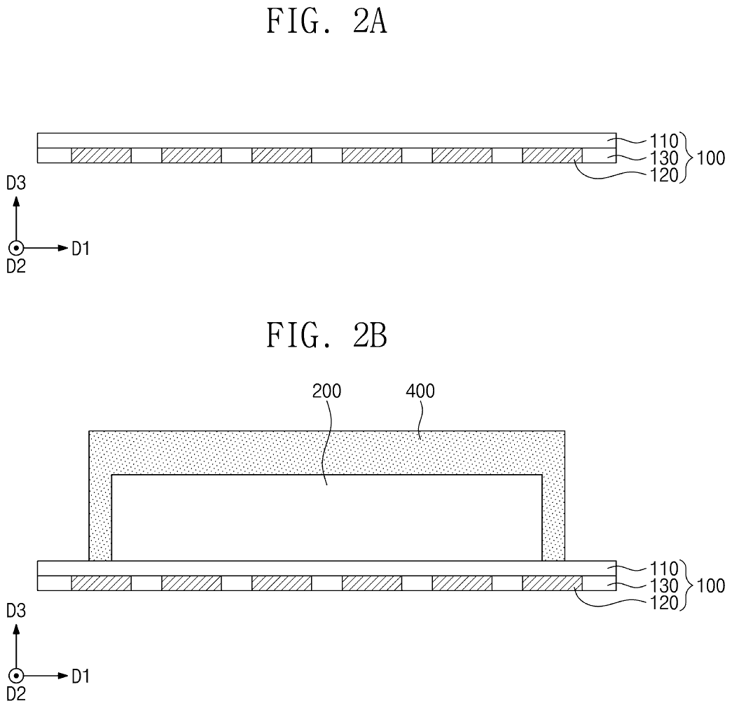

FIG. 1A is a sectional view illustrating a semiconductor package according to some embodiments. FIG. 1B is an enlarged view illustrating a portion ‘A’ of FIG. 1A. FIG. 1C is a plan view illustrating a core of the semiconductor package of FIGS. 1A and 1B.

Referring to FIG. 1A, a semiconductor package 2 may include a package substrate 100. The package substrate 100 may be, for example, a printed circuit board.

The package substrate 100 may include a substrate body 110, which has a top surface 110_T and a bottom surface 110_B, a plurality of substrate pads 120, which are provided on the bottom surface 110_B of the substrate body 110 and are spaced apart from each other, and a substrate protection layer 130, which is used to electrically disconnect the substrate pads 120 from each other.

The substrate body 110 may have a shape of a plate (i.e. is planar), which is extended in a first direction D1 and a second direction D2. The first and second directions D1, D2 may not be parallel to each other. For example, the first and second directions D1, D2 may be horizontal directions that are orthogonal to each other.

The substrate body 110 may include an insulating material. For example, the substrate body 110 may include a polymer material. For example, the substrate body 110 may be formed of or include at least one of a prepreg resin, a thermosetting epoxy resin, a thermoplastic epoxy resin, and a filler-containing resin. The substrate pads 120 may include a conductive material. The substrate protection layer 130 may include an insulating material. For example, the substrate protection layer 130 may include an oxide or nitride material. In some embodiments, the package substrate 100 may be a redistribution substrate including a redistribution insulating layer and a redistribution pattern.

A semiconductor device 200 may be disposed on a top surface 100_T of the package substrate 100. The semiconductor device 200 may be a semiconductor chip, which includes electronic components on a semiconductor substrate. The semiconductor device 200 may be, for example, a logic device, a memory device, or an image sensor device.

In some embodiments, a plurality of semiconductor devices 200 may be disposed on the package substrate 100. In some embodiments, the semiconductor device 200 may be electrically connected to the package substrate 100 in a flip-chip bonding manner. In some embodiments, the semiconductor device 200 may be electrically connected to the package substrate 100 in a wire bonding manner.

Solder balls 300, which are connected to the substrate pads 120, may be provided.

The solder ball 300 may include a conductive material. For example, the solder ball 300 may include at least one of bismuth (Bi), silver (Ag), tin (Sn), or copper (Cu).

The solder ball 300 may be in contact with a bottom surface 120_B of a substrate pad 120.

A core 310 may be provided. The solder ball 300 may enclose the core 310. The core 310 may include a magnetic layer 311 and a supporting element, layer, or body 312 on the magnetic layer 311.

A mold layer 400 may be provided on the package substrate 100. The mold layer 400 may be in contact with the top surface 110_T of the package substrate 100. The mold layer 400 may enclose the semiconductor device 200. The mold layer 400 may include an insulating material. For example, the mold layer 400 may include a polymer material.

A stiffener 500 may be provided on the package substrate 100. The stiffener 500 may be provided to enclose the mold layer 400. The stiffener 500 and the mold layer 400 may be spaced apart from each other. For example, the stiffener 500 may include copper, aluminum, polymer material, or stainless steel.

Referring to FIG. 1B, a bottom surface 312_B of the supporting element 312 may be in contact with the magnetic layer 311. A side surface 312_S of the supporting element 312 may be inclined at an angle relative to the bottom surface 312_B of the supporting element 312. A width of the supporting element 312 in the first direction D1 may decrease as a distance from the bottom surface 312_B increases in a direction toward a top surface 312_T. The bottom surface 312_B and the top surface 312_T of the supporting element 312 may be parallel to the first and second directions D1, D2.

The entire surface area of the top surface 312_T of the supporting element 312 may be smaller than the entire surface area of the bottom surface 312_B of the supporting element 312. Similarly, the entire surface area of the top surface 312_T of the supporting element 312 may be smaller than the entire surface area of a bottom surface 311_B of the magnetic layer 311 and the entire surface area of the top surface 312_T of the supporting element 312 may also be smaller than the entire surface area of a bottom surface 310_B of the core 310. In some embodiments, the bottom surface 310_B of the core 310 may be the same as the bottom surface 311_B of the magnetic layer 311. In some embodiments, the area of the bottom surface 311_B of the magnetic layer 311 may be substantially equal to the area of the bottom surface 312_B of the supporting element 312. A height or thickness of the magnetic layer 311 in a third direction D3 may be smaller than a height or thickness of the supporting element 312 in the third direction D3. The third direction D3 may not be parallel to the first and second directions D1, D2. For example, the third direction D3 may be a vertical direction orthogonal to the first and second directions D1, D2.

The top surface 312_T of the supporting element 312, the bottom surface 312_B of the supporting element 312, and the bottom surface 311_B of the magnetic layer 311 may be parallel to each other. The bottom surface 312_B of the supporting element 312 may be flat. The bottom surface 311_B of the magnetic layer 311 may be flat.

A width of the top surface 312_T of the supporting element 312 in the first direction D1 may be smaller than a width of the bottom surface 312_B of the supporting element 312 in the first direction D1. The width of the bottom surface 312_B of the supporting element 312 in the first direction D1 may be substantially equal to a width of the magnetic layer 311 in the first direction D1.

The top surface 312_T and the side surface 312_S of the supporting element 312 may be in contact with the solder ball 300. The bottom surface 311_B of the magnetic layer 311 may be in contact with the solder ball 300.

The supporting element 312 and the magnetic layer 311 may include a conductive material. In some embodiments, the magnetic layer 311 may include a ferromagnetic material. For example, the magnetic layer 311 may be formed of or include nickel (Ni). In some embodiments, the supporting element 312 may include an antiferromagnetic or paramagnetic material. For example, the supporting element 312 may be formed of or include copper (Cu).

The core 310 may include an upper portion 310_U and a lower portion 310_L of the core 310. The lower portion 310_L of the core 310 may include the magnetic layer 311 and a lower portion of the supporting element 312. The upper portion 310_U of the core 310 may include an upper portion of the supporting element 312. In some embodiments, a height or thickness of the lower portion 310_L of the core 310 in the third direction D3 may be substantially equal to a height or thickness of the upper portion 310_U of the core 310 in the third direction D3.

A volume of the upper portion 310_U of the core 310 may be smaller than a volume of the lower portion 310_L of the core 310. A mass of the upper portion 310_U of the core 310 may be smaller than a mass of the lower portion 310_L of the core 310. A center of mass CM of the core 310 may be located in the lower portion 310_L of the core 310.

In some embodiments, the center of mass CM of the core 310 is located in the lower portion 310_L of the core 310. That is, the center of mass CM is located below the vertical midpoint MP of the core 310, wherein the midpoint MP is the point on the center axis 310_C (i.e. parallel to the direction D3) halfway between the top surface 310_T of the core 310 and the bottom surface 310_B of the core 310.

The core 310 may have a center axis 310_C extending in the third direction D3. The core 310 may be provided to be axisymmetric with respect to the center axis 310_C. A distance between the side surface 312_S of the supporting element 312 and the center axis 310_C may decrease as a distance from the bottom surface 312_B of the supporting element 312 increases in a direction toward the top surface 312_T.

Referring to FIG. 1C, the top surface 312_T and the bottom surface 312_B of the supporting element 312 may have a circular shape. A diameter of the top surface 312_T may be smaller than a diameter of the bottom surface 312_B. When viewed in the plan view of FIG. 1C, the center of the top surface 312_T may coincide with the center of the bottom surface 312_B.

In conventional technology the core structure has a ball shape. During a surface mount technology (SMT) process, the solder ball may be deformed or wrapped in a biased manner, which may cause the core to become offset from the desired position within the solder ball. This may lead to a failure, such as a solder bridge.

In embodiments as disclosed herein, the core 310 has an overall shape that is axisymmetric about a vertical axis 310_C, and the center of mass CM of the core 310 is located in the lower portion 310_L of the core 310. Core structures of this construction can prevent or reduce the occurrence of the aforementioned internal deformation or warpage caused by a solder ball reflow in the SMT process.

In a method of fabricating a semiconductor package according to some embodiments, in a surface mount technology (SMT) process of connecting the solder ball 300 to a main board 1, which will be described with reference to FIG. 1D, the core 310 may have a bottom surface 310_B that is flat, and thus, it may be possible to reduce a change of the position of the core 310 and thereby to reduce a failure rate of the semiconductor package. In other words, the core 310 having a bottom surface 310_B that is flat may prevent the core 310 from moving undesirably, such as by rolling, when the solder ball 300 melts.

In a semiconductor package according to some embodiments, since a volume of the lower portion 310_L of the core 310 is larger than a volume of the upper portion 310_U, a center of mass CM of the core 310 may be located in the lower portion 310_L of the core 310. Since the center of mass CM is located in the lower portion 310_L of the core 310, it may be possible to reduce a change of the position of the core 310 in the SMT process, and thus, a failure rate of the semiconductor package may be lowered. In other words, the core 310 having a center of mass CM located in the lower portion 310_L may prevent the core 310 from moving undesirably when the solder ball 300 melts.

In a semiconductor package according to some embodiments, since the magnetic layer 311 or the supporting element 312 includes a ferromagnetic material, it may be possible to align the center axis 310_C of the core 310 to the third direction D3 using a magnetic field, during the process of placing the solder ball 300 and the core 310 on a bottom surface 100_B of the package substrate 100.

FIG. 1D is a sectional view illustrating a semiconductor package system, on which the semiconductor package of FIG. 1A is mounted.

Referring to FIG. 1D, the semiconductor package system may include a main board 1. The main board 1 may be a printed circuit board, a ceramic interconnection structure, a glass interconnection structure, or an interposer interconnection structure. The main board 1 may include a main substrate 10, mounting pads 11 on the main substrate 10, and a mounting insulating layer 12 between the mounting pads 11.

The main substrate 10 may be a plate-shaped structure, which is extended in the first and second directions D1, D2.

The mounting pads 11 may include a conductive material. The mounting insulating layer 12 may include an insulating material.

The semiconductor package 2 may be provided on the main board 1. The solder ball 300 may be disposed on a top surface 11_T of a mounting pad 11. The main board 1 and the semiconductor package 2 may be electrically connected to each other through the solder ball 300.

Top and bottom surfaces 100_T, 100_B of the package substrate 100, the semiconductor device 200, the mold layer 400, and the stiffener 500, which are mounted on the main board 1, may be bent or curved. The solder ball 300 of the semiconductor package 2, which is mounted on the main board 1, may be deformed.

In a semiconductor package according to some embodiments, a melting point of the core 310 may be higher than a melting point of the solder ball 300, and in this case, it may be possible to reduce deformation of the core 310 in a SMT process of mounting the package substrate 100 on the main board 1. This may make it possible to reduce deformation of the solder ball 300 in the SMT process and thereby to reduce a failure rate of the semiconductor package.

In a semiconductor package according to some embodiments, a bottom surface 310_B of the core 310 may be flat, and thus, it may be possible to reduce a change of the position of the core 310 in the SMT process. As a result, the solder ball 300 may be effectively supported by the core 310.

In a semiconductor package according to some embodiments, a lower portion 310_L of the core 310 may have a volume larger than its upper portion 310_U, a center of mass CM of the core 310 may be located in the lower portion 310_L of the core 310. Thus, it may be possible to effectively reduce a change of the position of the core 310 in the SMT process. As a result, the solder ball 300 may be effectively supported by the core 310.

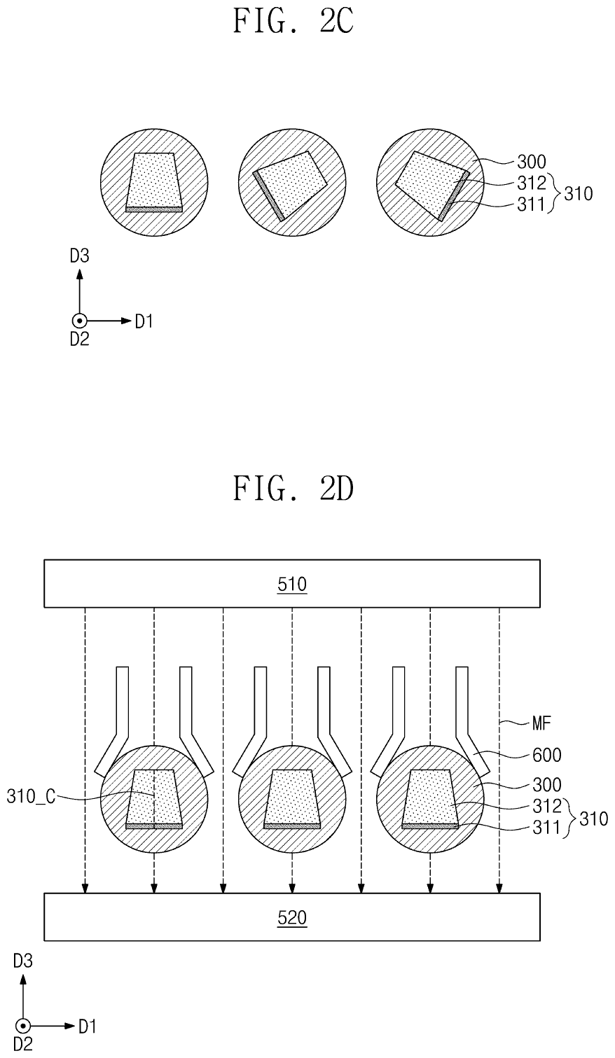

FIGS. 2A, 2B, 2C, 2D, and 2E are sectional views illustrating a method of fabricating the semiconductor package of FIGS. 1A, 1B, and 1C.

Referring to FIG. 2A, the package substrate 100 including the substrate body 110, the substrate pad 120, and the substrate protection layer 130 may be provided. Referring to FIG. 2B, the semiconductor device 200 may be mounted on the package substrate 100. The semiconductor device 200 may be mounted on the package substrate 100 in a flip chip manner or a wire bonding manner. The mold layer 400 may be formed on the semiconductor device 200.

Referring to FIG. 2C, the solder balls 300 and the cores 310 may be formed.

Referring to FIG. 2D, transporting tools 600 may be used to deliver the cores 310 and the solder balls 300. In some embodiments, the transporting tool 600 may include a vacuum tube which is used to grasp the solder balls 300.

The cores 310 and the solder balls 300 may be placed between a first magnetic element 510 and a second magnetic element 520 using the transporting tool 600. In some embodiments, each of the first and second magnetic elements 510, 520 may be a plate-shaped structure extended in the first and second directions D1, D2. The cores 310 and the solder balls 300 may be arranged in the first and second directions D1, D2.

In some embodiments, each of the first and second magnetic elements 510, 520 may include a ferromagnetic material. In some embodiments, each of the first and second magnetic elements 510, 520 may include an electromagnet.

A magnetic field MF may be produced in a space between the first and second magnetic elements 510, 520. A direction of the magnetic field MF may be parallel to the third direction D3. In some embodiments, the magnetic field MF may be produced in a direction from the first magnetic element 510 toward the second magnetic element 520. In other embodiments, the magnetic field MF may be produced in a direction from the second magnetic element 520 toward the first magnetic element 510.

The magnetic field MF may exert a torque on the cores 310 and the solder balls 300. For example, the torque by the magnetic field MF may be exerted on the ferromagnetic material in the cores 310. In this case, due to the magnetic field MF, the solder balls 300 and the cores 310 may be rotated and reoriented in such a way that the center axes CA of the cores 310 are aligned to each other. The center axes of the cores 310 may be parallel to the third direction D3.

Referring to FIG. 2E, the solder balls 300 may be connected to the package substrate 100. The solder balls 300 may be connected to the substrate pads 120. The center axes of the cores 310 in the solder balls 300, which are connected to the substrate pads 120, may be parallel to the third direction D3. In a method of fabricating a semiconductor package according to some embodiments, the magnetic field MF may be used to reorient and align the center axis 310_C of the core 310, and the bottom surface 310_B of the core 310 may be flat.

In a method of fabricating a semiconductor package according to some embodiments, the magnetic field MF may be used to align the center axis 310_C of the core 310, and thus, a center of mass CM of the core 310 may be located in a lower portion 310_L of the core 310.

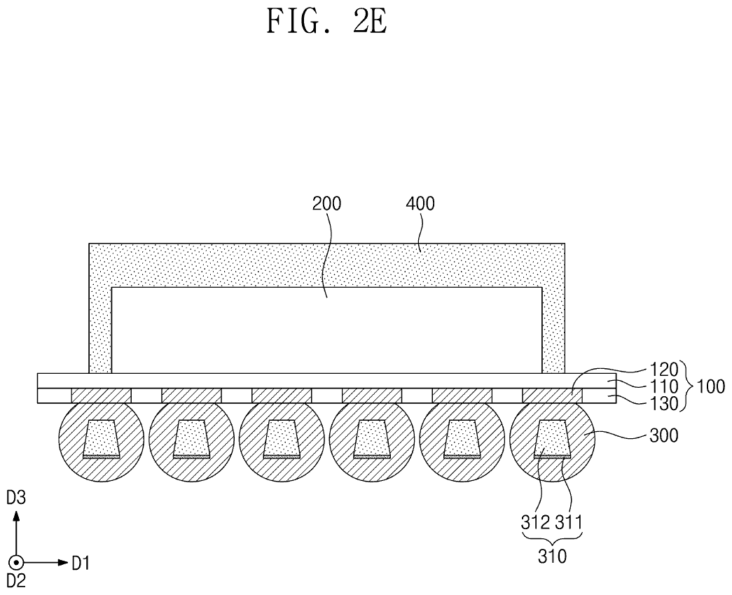

FIG. 3 is a sectional view illustrating a core of a semiconductor package according to some embodiments.

Referring to FIG. 3, a solder ball 300a may enclose a core 310a. The core 310a may include a ferromagnetic material. For example, the core 310a may include nickel (Ni).

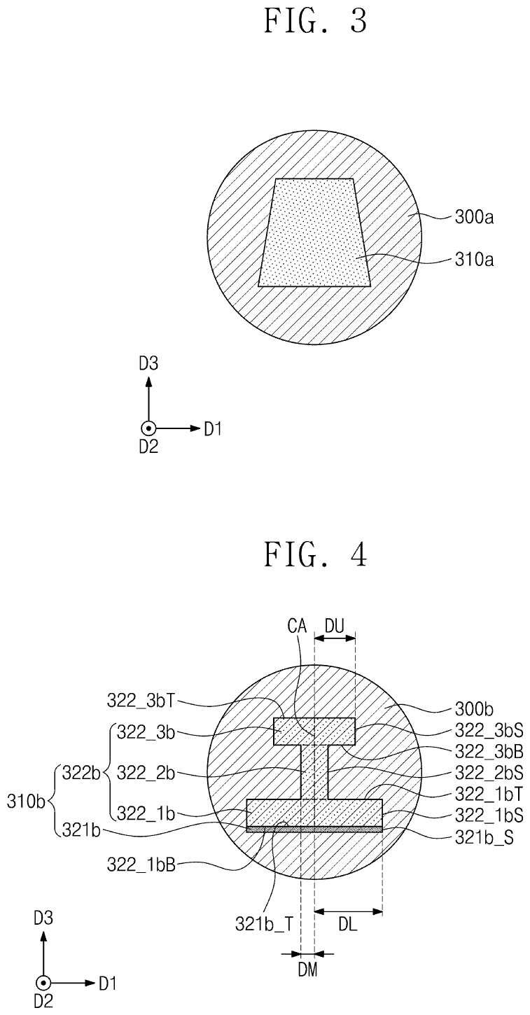

FIG. 4 is a sectional view illustrating a core of a semiconductor package according to some embodiments.

Referring to FIG. 4, a core 310b may include a magnetic layer 321b and a supporting element 322b. The supporting element 322b may include a first supporting part 322_1b, a second supporting part 322_2b, and a third supporting part 322_3b. The supporting parts 322_1b, 322_2b, 322_3b may be separately formed or discrete parts that are affixed to one another to form the supporting element 322b or may be portions or layers of a unitarily formed or monolithic component.

A solder ball 300b may enclose the core 310b. The core 310b may have a center axis CA extending in the third direction D3. The first, second, and third supporting parts 322_1b, 322_2b, 322_3b may include a paramagnetic or antiferromagnetic material. The first, second, and third supporting parts 322_1b, 322_2b, 322_3b may be axisymmetric with respect to the center axis CA. The first, second, and third supporting parts 322_1b, 322_2b, 322_3b may be connected to each other.

A top surface 322_1bT of the first supporting part 322_1b may be connected to a side surface 322_2bS of the second supporting part 322_2b. The side surface 322_2bS of the second supporting part 322_2b may be connected to a bottom surface 322_3bB of the third supporting part 322_3b.

The first supporting part 322_1b may be provided on the magnetic layer 321b. A bottom surface 322_1bB of the first supporting part 322_1b may be in contact with a top surface 321b_T of the magnetic layer 321b. In some embodiments, an area of the bottom surface 322_1bB of the first supporting part 322_1b may be equal to an area of the top surface 321b_T of the magnetic layer 321b.

A width of the first supporting part 322_1b in the first direction D1 may be substantially equal to a width of the magnetic layer 321b in the first direction D1. A width of the first supporting part 322_1b in the second direction D2 may be substantially equal to a width of the magnetic layer 321b in the second direction D2.

The top surface 322_1bT of the first supporting part 322_1b may be in contact with the solder ball 300b. An area of the top surface 322_1bT of the first supporting part 322_1b may be smaller than the area of the bottom surface 322_1bB of the first supporting part 322_1b.

A side surface 322_1bS of the first supporting part 322_1b may be in contact with the solder ball 300b. The side surface 322_1bS of the first supporting part 322_1b may be coplanar with a side surface 321b_S of the magnetic layer 321b. A distance DL between the center axis CA and the side surface 322_1bS of the first supporting part 322_1b may be constant.

The second supporting part 322_2b may be disposed on the first supporting part 322_1b. The second supporting part 322_2b may be disposed between the first supporting part 322_1b and the third supporting part 322_3b. The side surface 322_2bS of the second supporting part 322_2b may be in contact with the solder ball 300b. A distance DM between the center axis CA and the side surface 322_2bS of the second supporting part 322_2b may be constant. The distance DM between the center axis CA and the side surface 322_2bS of the second supporting part 322_2b may be smaller than a distance DL between the center axis CA and the side surface 322_1bS of the first supporting part 322_1b.

The third supporting part 322_3b may be disposed on the second supporting part 322_2b. A side surface 322_3bS and a top surface 322_3bT of the third supporting part 322_3b may be in contact with the solder ball 300b. A distance DU between the center axis CA and the side surface 322_3bS of the third supporting part 322_3b may be constant. The distance DU between the center axis CA and the side surface 322_3bS of the third supporting part 322_3b may be larger than the distance DM between the center axis CA and the side surface 322_2bS of the second supporting part 322_2b. The distance DU between the center axis CA and the side surface 322_3bS of the third supporting part 322_3b may be smaller than a distance DL between the center axis CA and the side surface 322_1bS of the first supporting part 322_1b. An area of the top surface 322_3bT of the third supporting part 322_3b may be smaller than an area of a bottom surface 322_1bB of the first supporting part 322_1b.

The bottom surface 322_3bB of the third supporting part 322_3b may be in contact with the solder ball 300b. An area of the bottom surface 322_3bB of the third supporting part 322_3b may be smaller than the area of the top surface 322_3bT of the third supporting part 322_3b.

A width of the first supporting part 322_1b in the first direction D1 may be larger than a width of the third supporting part 322_3b in the first direction D1. The width of the first supporting part 322_1b in the first direction D1 may be larger than a width of the second supporting part 322_2b in the first direction D1. The width of the third supporting part 322_3b in the first direction D1 may be larger than a width of the second supporting part 322_2b in the first direction D1. Each of the first, second, and third supporting parts 322_1b, 322_2b, 322_3b may have a circular shape, when viewed in a plan view parallel to the first and second directions D1, D2.

The bottom surface 322_1bB of the first supporting part 322_1b, the top surface 322_1bT of the first supporting part 322_1b, the bottom surface 322_3bB of the third supporting part 322_3b, and the top surface 322_3bT of the third supporting part 322_3b may be parallel to each other. The bottom surface 322_1bB of the first supporting part 322_1b, the top surface 322_1bT of the first supporting part 322_1b, the bottom surface 322_3bB of the third supporting part 322_3b, and the top surface 322_3bT of the third supporting part 322_3b may be parallel to the first and second directions D1, D2. The bottom surface 322_1bB of the first supporting part 322_1b, the top surface 322_1bT of the first supporting part 322_1b, the bottom surface 322_3bB of the third supporting part 322_3b, and the top surface 322_3bT of the third supporting part 322_3b may be perpendicular to the center axis CA.

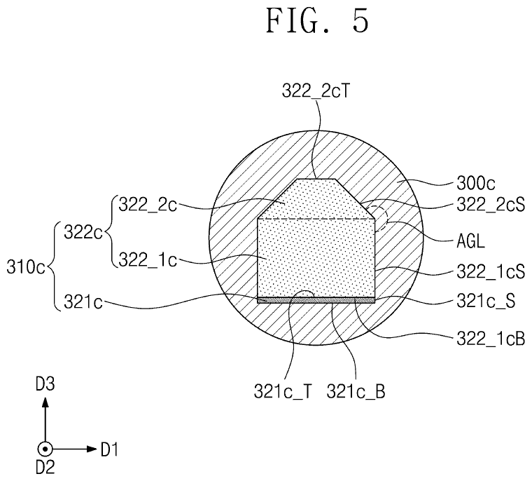

FIG. 5 is a sectional view illustrating a core of a semiconductor package according to some embodiments.

Referring to FIG. 5, a core 310c may include a magnetic layer 321c and a supporting element 322c. A solder ball 300c may enclose the core 310c. The supporting element 322c may include a first supporting portion 322_1c and a second supporting portion 322_2c on the first supporting portion 322_1c. The first supporting portion 322_1c may be provided on the magnetic layer 321c.

A side surface 322_1cS of the first supporting portion 322_1c, a top surface 322_2cT of the second supporting portion 322_2c, a side surface 322_2cS of the second supporting portion 322_2c, a side surface 321c_S of the magnetic layer 321c, and a bottom surface 321c_B of the magnetic layer 321c may be in contact with the solder ball 300c.

An area of a bottom surface 322_1cB of the first supporting portion 322_1c may be larger than an area of the top surface 322_2cT of the second supporting portion 322_2c. An area of the bottom surface 322_1cB of the first supporting portion 322_1c may be substantially equal to an area of a top surface 321c_T of the magnetic layer 321c. The side surface 322_2cS of the second supporting portion 322_2c may be inclined at an angle relative to the bottom surface 322_1cB of the first supporting portion 322_1c. The bottom surface 322_1cB of the first supporting portion 322_1c may be parallel to the first and second directions D1, D2.

The side surface 322_1cS of the first supporting portion 322_1c may be perpendicular to the first and second directions D1, D2. The side surface 322_1cS of the first supporting portion 322_1c may be extended in the third direction D3.

The side surfaces 322_1cS, 322_2cS of the first and second supporting portions 322_1c, 322_2c may be connected to each other. An angle AGL between the side surfaces 322_1cS, 322_2cS of the first and second supporting portions 322_1c, 322_2c may range from 90° to 180°.

A width of the first supporting portion 322_1c in the first direction D1 may be constant. A width of the second supporting portion 322_2c in the first direction D1 may decrease as a distance to the top surface 322_2cT decreases.

In some embodiments, a volume of the second supporting portion 322_2c may be smaller than a volume of the first supporting portion 322_1c.

In some embodiments, the first supporting portion 322_1c and the second supporting portion 322_2c may include the same material. In some embodiments, the first supporting portion 322_1c and the second supporting portion 322_2c may include a paramagnetic or antiferromagnetic material. The magnetic layer 321c may include a ferromagnetic material.

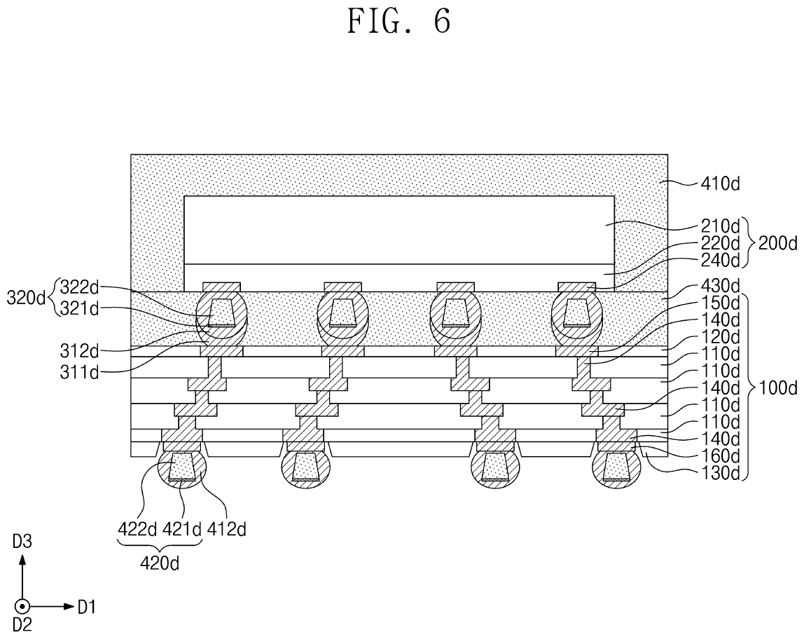

FIG. 6 is a sectional view illustrating a semiconductor package according to some embodiments.

Referring to FIG. 6, the semiconductor package may include a first structure 100d, a second structure 200d, first solder balls 312d, solder pastes 311d, first cores 320d, second solder balls 412d, second cores 420d, a first mold layer 410d, and a second mold layer 430d.

The first structure 100d may include inner insulating layers 110d, an upper insulating layer 120d, a first lower insulating layer 130d, inner patterns 140d, upper connection patterns 150d, and first lower connection patterns 160d. The second structure 200d may include a substrate 210d, an interconnection structure 220d, and second lower connection patterns 240d.

The first structure 100d may be a redistribution substrate. In some embodiments, the first structure 100d may be similar to the package substrate 100 of FIG. 1B. The second structure 200d may be similar to the semiconductor device 200 of FIG. 1B.

Each of the inner insulating layers 110d, the upper insulating layer 120d, and the first lower insulating layer 130d may be a plate-shaped structure, which is extended in the first and second directions D1, D2. The first lower insulating layer 130d, the inner insulating layers 110d, and the upper insulating layer 120d may be sequentially stacked in the third direction D3. The inner insulating layers 110d, the upper insulating layer 120d, and the first lower insulating layer 130d may include an insulating material.

The inner patterns 140d may be conductive patterns that are disposed in the first structure 100d. The inner patterns 140d may be enclosed by the inner insulating layers 110d. The inner patterns 140d may be disposed in the inner insulating layers 110d.

The inner patterns 140d may include a via portion for vertical interconnection and a wire portion for horizontal interconnection. The via portion of the inner pattern 140d may be placed at a level higher than the wiring portion.

First and second solder pastes 311d, 411d may include a conductive material. For example, the first and second solder pastes 311d, 411d may include at least one of bismuth, silver, tin, or copper.

The first solder paste 311d may be connected to the upper connection pattern 150d. The first solder ball 312d may be connected to the second lower connection pattern 240d. The first core 320d may include a first magnetic layer 321d and a first supporting element 322d on the first magnetic layer 321d.

The second solder ball 412d may be connected to the first lower connection pattern 160d. The second core 420d may include a second magnetic layer 421d and a second supporting element 422d on the second magnetic layer 421d.

The first mold layer 410d may be provided on the second structure 200d. The first mold layer 410d may enclose the second structure 200d. The first mold layer 410d may include a polymer material. The second mold layer 430d may be provided between the first structure 100d and the second structure 200d. The second mold layer 430d may be in contact with the interconnection structure 220d, the first mold layer 410d, the upper insulating layer 120d, the first solder paste 311d, and the first solder ball 312d. The second mold layer 430d may include a polymer material. In some embodiments, the second mold layer 430d, the first solder ball 312d, the solder paste 311d, and the first core 320d may be formed after the formation of the first structure 100d and the first mold layer 410d. In some embodiments, the second solder ball 412d and the second core 420d may be formed after the formation of the first solder ball 312d, the solder paste 311d, the first core 320d, and the second mold layer 430d.

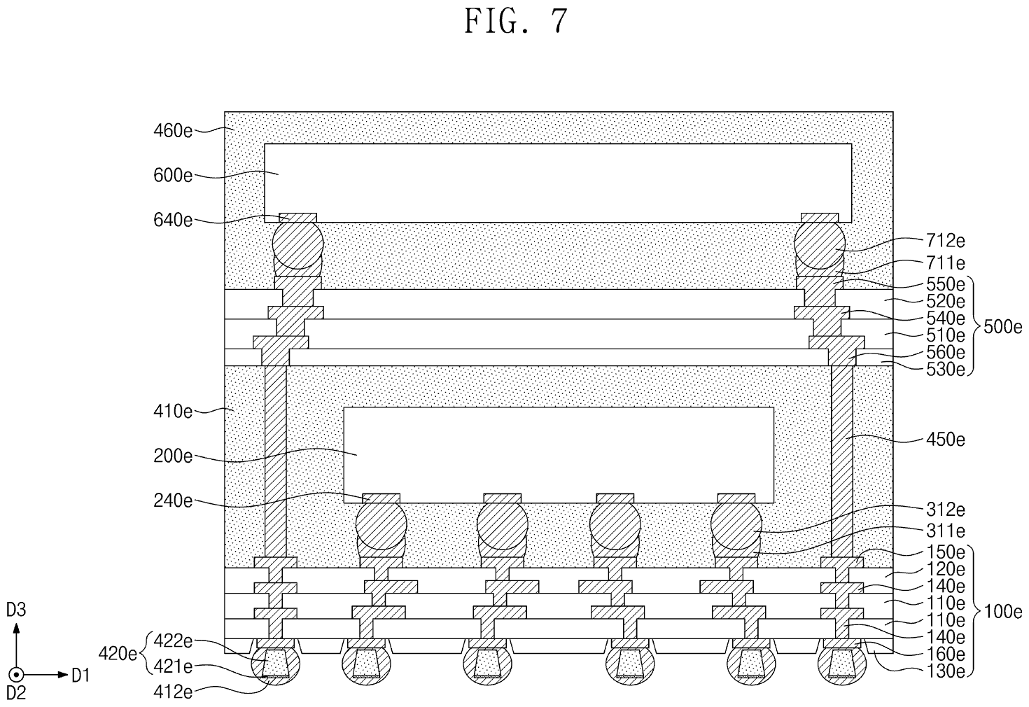

FIG. 7 is a sectional view illustrating a semiconductor package according to some embodiments.

Referring to FIG. 7, the semiconductor package may include a first structure 100e, a second structure 200e, a third structure 500e, a fourth structure 600e, a first solder paste 311e, a first solder ball 312e, a second solder paste 711e, a second solder ball 712e, a third solder ball 412e, a third core 420e, a first mold layer 410e, a second mold layer 460e, and connection vias 450e.

The first structure 100e may include a first inner insulating layer 110e, a first upper insulating layer 120e, a first lower insulating layer 130e, first inner patterns 140e, first upper connection patterns 150e, and first lower connection patterns 160e. The first structure 100e may be a redistribution substrate.

The second structure 200e may be disposed on the first structure 100e. The second structure 200e may include a second lower connection pattern 240e. The second structure 200e may be a semiconductor chip.

The first solder pastes 311e and the first solder balls 312e may be provided between the first structure 100e and the second structure 200e. The first structure 100e and the second structure 200e may be electrically connected to each other by the first solder paste 311e and the first solder ball 312e.

The first mold layer 410e may be provided to enclose the second structure 200e, the first solder balls 312e, and the first solder pastes 311e. The connection via 450e may be provided to penetrate the first mold layer 410e and may be connected to the first upper connection pattern 150e of the first structure 100e.

The third structure 500e may be provided on the first mold layer 410e. The third structure 500e may include a second inner insulating layer 510e, a second upper insulating layer 520e, a second lower insulating layer 530e, second inner patterns 540e, second upper connection patterns 550e, and third lower connection patterns 560e. The connection via 450e may be connected to the third lower connection pattern 560e.

The fourth structure 600e may be disposed on the third structure 500e. The fourth structure 600e may include a fourth lower connection pattern 640e. The fourth structure 600e may be a semiconductor chip.

The second solder pastes 711e and the second solder balls 712e may be provided between the third structure 500e and the fourth structure 600e. The third structure 500e and the fourth structure 600e may be electrically connected to each other by the second solder paste 711e and the second solder ball 712e.

The second mold layer 460e may be provided to enclose the fourth structure 600e, the second solder balls 712e, and the second solder pastes 711e.

The third solder balls 412e may be provided to be in contact with bottom surfaces 160e_B of the first lower connection patterns 160e of the first structure 100e. The third core 420e, which is enclosed by the third solder ball 412e, may be provided. The third core 420e may include a third magnetic layer 421e and a third supporting element 422e on the third magnetic layer 421e.

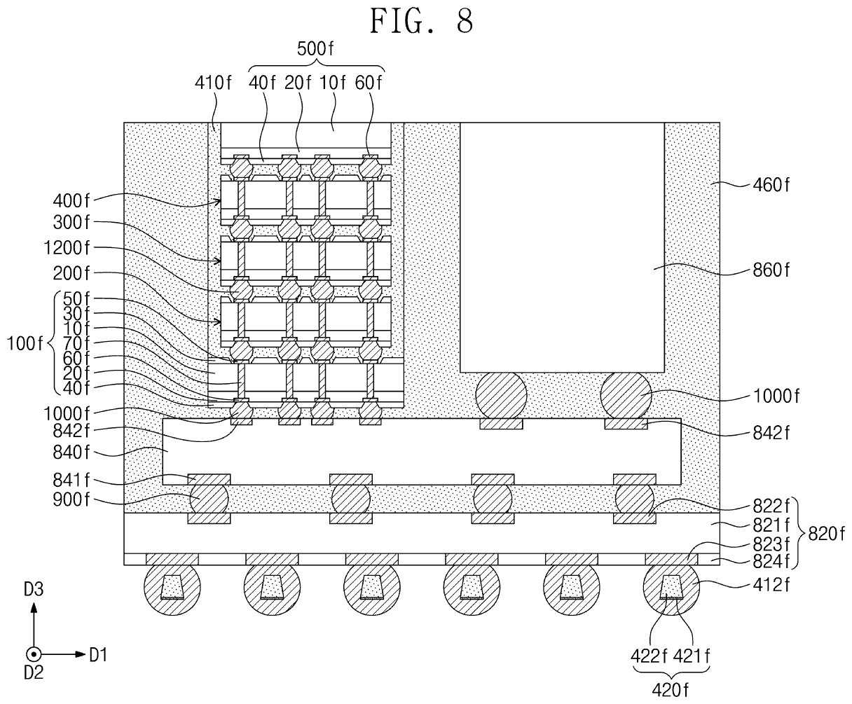

FIG. 8 is a sectional view illustrating a semiconductor package according to some embodiments.

Referring to FIG. 8, the semiconductor package may include a package substrate 820f. The package substrate 820f may include a substrate body 821f, a first upper connection pattern 822f, a substrate pad 823f, and a substrate protection layer 824f. The package substrate 820f may be, for example, a printed circuit board.

An interposer 840f may be provided on the package substrate 820f. The interposer 840f may include a first lower connection pattern 841f and a second upper connection pattern 842f.

First solder balls 900f may be provided between the package substrate 820f and the interposer 840f. The first solder ball 900f may be connected to the first lower connection pattern 841f and the first upper connection pattern 822f.

A processor chip 86Of may be provided on the interposer 840f. For example, the processor chip 860f may be a graphics processing unit (FPU) or a central processing unit (CPU). Second solder balls 1000f may be provided between the processor chip 860f and the interposer 840f. The second solder ball 1000f may be connected to the processor chip 860f and the second upper connection pattern 842f.

A first structure 100f, a second structure 200f, a third structure 300f, a fourth structure 400f, and a fifth structure 500f, which are sequentially disposed in the third direction D3, may be provided on the interposer 840f.

Each of the first, second, third, and fourth structures 100f, 200f, 300f, 400f may include a substrate 10f, an interconnection structure 20f, an upper insulating layer 30f, a lower insulating layer 40f, upper connection patterns 50f, lower connection patterns 60f, and penetration vias 70f. The penetration vias 70f may include a conductive material.

The fifth structure 500f may include the substrate 10f, the interconnection structure 20f, the lower insulating layer 40f, and the second lower connection patterns 60f.

The first to fifth structures 100f, 200f, 300f, 400f, 500f may be a semiconductor chip including a logic device or a memory device. In some embodiments, the first structure 100f may be a redistribution substrate or a printed circuit board.

The first to fifth structures 100f, 200f, 300f, 400f, 500f may be a semiconductor chip including a logic device or a memory device. In some embodiments, the first structure 100f may be a redistribution substrate or a printed circuit board.

Third solder balls 1000f may be provided between the first structure 100f and the interposer 840f. The third solder ball 1000f may be connected to the second lower connection pattern 60f and the second upper connection pattern 842f.

Fourth solder balls 1200f may be provided between the first structure 100f and the second structure 200f, between the second structure 200f and the third structure 300f, between the third structure 300f and the fourth structure 400f, and between the fourth structure 400f and the fifth structure 500f.

Fifth solder balls 412f, which are electrically connected to the package substrate 820f, may be provided. The fifth solder ball 412f may be electrically connected to the package substrate 820f. Fifth cores 420f, which are enclosed by the fifth solder ball 412f, may be provided. The fifth core 420f may include a fifth magnetic layer 421f and a fifth supporting element 422f on the fifth magnetic layer 421f. The semiconductor package may be mounted on the main board through the fifth solder ball 412f.

A first mold layer 410f may be provided to cover the first, second, third, and fourth structures 100f, 200f, 300f, 400f and the fourth solder balls 1200f. A second mold layer 460f may be provided to cover the package substrate 820f, the first solder ball 900f, the interposer 840f, second solder balls 1012f, and third solder balls 1112f.

In a semiconductor package according to some embodiments, a core 310 in a solder ball may have a center of mass CM, which is located in a lower portion thereof, and may have a bottom surface, which is aligned to a desired direction. Thus, when a package substrate is mounted on a main board, it may be possible to prevent or suppress the position of the core 310 from being unintentionally changed.

While example embodiments have been particularly shown and described, it will be understood by one of ordinary skill in the art that variations in form and detail may be made therein without departing from the spirit and scope of the attached claims.

What is claimed is:

1. A semiconductor package, comprising:
a package substrate including a substrate pad;
a solder ball in contact with a bottom surface of the substrate pad; and
a core enclosed by the solder ball,
wherein an area of a bottom surface of the core is larger than an area of a top surface of the core.

2. The semiconductor package of claim 1, further comprising:
a semiconductor device including a connection pattern; and
a solder paste in contact with the connection pattern and the solder ball.

3. The semiconductor package of claim 1, wherein:
the core comprises a supporting element and a magnetic layer in contact with a bottom surface of the supporting element;
the magnetic layer comprises a ferromagnetic material; and
the supporting element comprises a paramagnetic or antiferromagnetic material.

4. The semiconductor package of claim 3, wherein an area of a top surface of the magnetic layer is substantially equal to an area of the bottom surface of the supporting element.

5. The semiconductor package of claim 3, wherein a thickness of the magnetic layer is smaller than a thickness of the supporting element.

6. The semiconductor package of claim 1, wherein a side surface of the core is inclined at an angle relative to the bottom surface of the core.

7. The semiconductor package of claim 1, wherein:
the core is axisymmetric with respect to a center axis of the core;
the core comprises:
a first supporting part;
a second supporting part on the first supporting part; and
a third supporting part on the second supporting part, and
a distance from the center axis of the core to a side surface of the second supporting part is smaller than a distance from the center axis of the core to a side surface of the first supporting part.

8. The semiconductor package of claim 7, wherein a distance from the center axis of the core to a side surface of the third supporting part is smaller than the distance from the center axis of the core to the side surface of the first supporting part.

9. The semiconductor package of claim 1, wherein:
the core comprises a first supporting part and a second supporting part on the first supporting part, and
a side surface of the second supporting part is inclined at an angle relative to a bottom surface of the first supporting part.

10. A semiconductor package, comprising:
a package substrate including a substrate pad;
a solder ball in contact with a bottom surface of the substrate pad; and
a core enclosed by the solder ball,
wherein a volume of a lower portion of the core is larger than a volume of an upper portion of the core.

11. The semiconductor package of claim 10, wherein a mass of the lower portion of the core is larger than a mass of the upper portion of the core.

12. The semiconductor package of claim 10, wherein a height of the upper portion of the core is substantially equal to a height of the lower portion of the core.

13. The semiconductor package of claim 10, wherein:
the lower portion of the core comprises a magnetic layer, and
the magnetic layer comprises a ferromagnetic material.

14. The semiconductor package of claim 13, wherein the magnetic layer comprises nickel (Ni).

15. The semiconductor package of claim 13, wherein a bottom surface of the magnetic layer is in contact with the solder ball.

16. The semiconductor package of claim 10, wherein a side surface of the upper portion of the core is inclined at an angle relative to a bottom surface of the core.

17. A semiconductor package, comprising:
a package substrate including a connection pattern;
a semiconductor device on the package substrate;
a mold layer disposed on the package substrate and covering the semiconductor device;
a stiffener disposed on the package substrate and enclosing the mold layer;
a solder ball in contact with a bottom surface of the connection pattern; and
a core enclosed by the solder ball,
wherein a top surface and a bottom surface of the core each have a circular shape, and
wherein a diameter of the bottom surface of the core is larger than a diameter of the top surface of the core.

18. The semiconductor package of claim 17, wherein:
the core comprises a supporting element and a magnetic layer in contact with a bottom surface of the supporting element, and
the magnetic layer comprises a ferromagnetic material.

19. The semiconductor package of claim 17, wherein the core has a center axis, which is perpendicular to the top and bottom surfaces of the core, and the core is axisymmetric with respect to the center axis.

20. The semiconductor package of claim 17, wherein the bottom surface of the core is flat.
